(19) United States
(12) Patent Application Publication
(10) Pub. No.: US 2012/0287591 A1
(43) Pub. Date: Nov. 15, 2012

(54) CONNECTION MEMBER

(75) Inventor: Shigeki Ishikawa, Kanagawa (JP)

(73) Assignee: NHK SPRING CO., LTD., Yokohama-shi ,Kanagawa (JP)

(21) Appl. No.: 13/511,765

(22) PCT Filed: Nov. 24, 2010
(86) PCT No.: PCT/JP2010/070888

§ 371 Date: May 24, 2012

(30) Foreign Application Priority Data
Nov. 24, 2009 (JP) 2009-266845

(51) Int. Cl. H05K 1/14

(52) U.S. Cl. 361/803

(57) ABSTRACT

A connection member that connects different boards, includes a plurality of conductive elastic members each of which includes two contact portions that are in contact with the different boards at ends, respectively, and an elastic portion that is provided between the two contact portions and is stretchable according to a force applied from outside the connection member, and an insulating restraining member that restrains movement of each of the elastic members by holding part of each of the elastic members, so that the force due to board vibrations applied to a joint of solder or the like can be relaxed.

### FIELD

The present invention relates to a connection member that connects boards.

### BACKGROUND

Conventionally, leads or flexible printed circuits (FPCs: Flexible Printed Circuits) are used as connection members to connect boards such as circuit boards and the wiring on boards. These connection members are flexible and deformable, therefore, they are used for connections between movable parts. Especially, an FPC has a structure in which a circuit formed from a metal foil is sandwiched between insulating films and has a thickness as thin as tens of pm (micrometers), therefore, it is bendable, so that an FPC can be used even in a narrow space.

The above-described connection member is fixed to each board with solder or the like to connect boards. Current can be reliably caused to flow even when a movable member is moved by joining the boards to the connection member with solder or the like, therefore, it is important to correctly fix the connection member to the boards. Thus, as a method of securely attaching solder while preventing leakage of the solder from a joint, a method of forming grooves on the solder joint on boards and crimping the connection member is disclosed (for example, see Patent Literature 1).

### CITATION LIST

### Patent Literature

Patent Literature 1: Japanese Patent Application Laid-open 2007-258410

### SUMMARY

### Technical Problem

However, even with the method disclosed in Patent Literature 1, there is a problem in that a load is placed on a crimped portion of solder or the like due to the transmission of vibrations of the movable member to the connection member, such as an FPC, therefore, solder or the like is stripped or damaged and the connection member and the boards becomes disconnected from each other, thereby interrupting current flow between the boards. Especially, because an FPC is bendable but not stretchable, solder or the like is stripped and damaged in some cases at a joint due to a force applied in a stretching direction or a force due to torsion.

The present invention is achieved in view of the above and has an object to provide a connection member capable of preventing stripping and damage of solder or the like at a joint due to vibrations with a board.

### Solution to Problem

To solve the problem described above and achieve the object, a connection member that connects different boards, comprises: a plurality of conductive elastic members each of which includes two contact portions that are in contact with the different boards at ends, respectively, and an elastic portion that is provided between the two contact portions and is stretchable according to a force applied from outside the connection member; and an insulating restraining member that restrains movement of each of the elastic members by holding part of each of the elastic members.

In the connection member according to the present invention as set forth in the invention described above, a plurality of groove portions, which extend in directions parallel to each other and each of which holds at least the elastic portion, is formed on the restraining member.

In the connection member according to the present invention as set forth in the invention described above, the groove portion includes an approximately columnar accommodation hole that accommodates and holds part of the elastic member, and an approximately columnar opening that communicates with the accommodation hole and has a diameter smaller than a diameter of the accommodation hole.

In the connection member according to the present invention as set forth in the invention described above, the groove portions are formed on one side of the restraining member.

In the connection member according to the present invention as set forth in the invention described above, the restraining member further includes a lid that covers the groove portions.

In the connection member according to the present invention as set forth in the invention described above, the restraining member has a rectangular parallelepiped shape, and includes a plurality of approximately cylindrical holes that have a cross-sectional shape, through which the elastic portion is capable of being inserted, and extend through opposite side surfaces of the rectangular parallelepiped shape.

In the connection member according to the present invention as set forth in the invention described above, the elastic member is formed of a wire rod, the elastic portions each have a zigzag shape repeating S shape, formation surfaces of the zigzag shape are parallel to each other, and a width in a direction in which the zigzag shape of the elastic portion reciprocates is larger than an interval between adjacent elastic members.

In the connection member according to the present invention as set forth in the invention described above, the contact portions are parallel to each other and pass a same plane, and the plane is perpendicular to the formation surfaces of the zigzag shape.

### Advantageous Effects of Invention

The connection member according to the present invention is such that part of a conductive wire connecting boards is formed of an elastic member to reduce a load due to vibrations applied to a joint of the boards and the connection member, therefore, when the boards vibrate, the force due to vibrations is attenuated by the elastic member and the force applied to the joint of the boards and the connection member is suppressed, so that an effect is obtained in that stripping and damage of solder or the like at the joint due to vibrations can be prevented and current flow between the boards can be stabilized.

### BRIEF DESCRIPTION OF DRAWINGS

FIG. 1 is a schematic diagram illustrating a schematic configuration of a connection member according to a first embodiment of the present invention.

FIG. 2 is an exploded perspective view illustrating each configuration of the connection member according to the first embodiment of the present invention.

FIG. 3 is a diagram illustrating connection between the connection member and boards according to the first embodiment of the present invention.

FIG. 4A is a diagram illustrating an operation in response to vibrations of the connection member according to the first embodiment of the present invention.

FIG. 4B is a diagram illustrating an operation in response to vibrations of the connection member according to the first embodiment of the present invention.

FIG. 5 is an exploded perspective view illustrating each configuration of a connection member according to a second embodiment of the present invention.

FIG. 6 is a top view illustrating a configuration of a main part of the connection member according to the second embodiment of the present invention. FIG. 7 is an exploded perspective view illustrating each configuration of a connection member according to a third embodiment of the present invention.

FIG. 8 is a diagram illustrating connection between the connection member and boards according to the third embodiment of the present invention.

FIG. 9 is a top view illustrating a configuration of a connection member that is a modified example of the third embodiment of the present invention.

FIG. 10 is a side view of the connection member shown in FIG. 9 viewed from an arrow A direction.

FIG. 11 is a perspective view illustrating a configuration of a connection member according to a fourth embodiment of the present invention.

FIG. 12 is a top view of the connection member shown in FIG. 11 viewed from an arrow B direction.

FIG. 13 is a side view of the connection member shown in FIG. 11 viewed from an arrow C direction.

FIG. 14 is a top view illustrating a configuration of a connection member according to a fifth embodiment of the present invention.

FIG. 15 is a side view of the connection member shown in FIG. 14 viewed from an arrow D direction.

FIG. 16 is a perspective view illustrating a configuration of a connection member according to a sixth embodiment of the present invention.

FIG. 17 is a perspective view illustrating a configuration of a connection member that is a modified example of the sixth embodiment of the present invention.

FIG. 18 is a perspective view illustrating a configuration of a connection member according to another embodiment of the present invention.

FIG. 19 is a perspective view illustrating a configuration of a connection member according to still another embodiment of the present invention.

### DESCRIPTION OF EMBODIMENTS

Embodiments of the present invention will be explained below in detail with reference to the drawings. The present invention is not limited to the following embodiments. Each drawing referred to in the following explanation only schematically illustrates the shape, the size, and the positional relationship to be able to understand the content of the present invention and therefore, the present invention is not limited to only the shape, the size, and the positional relationship illustrated in each drawing.

### First Embodiment

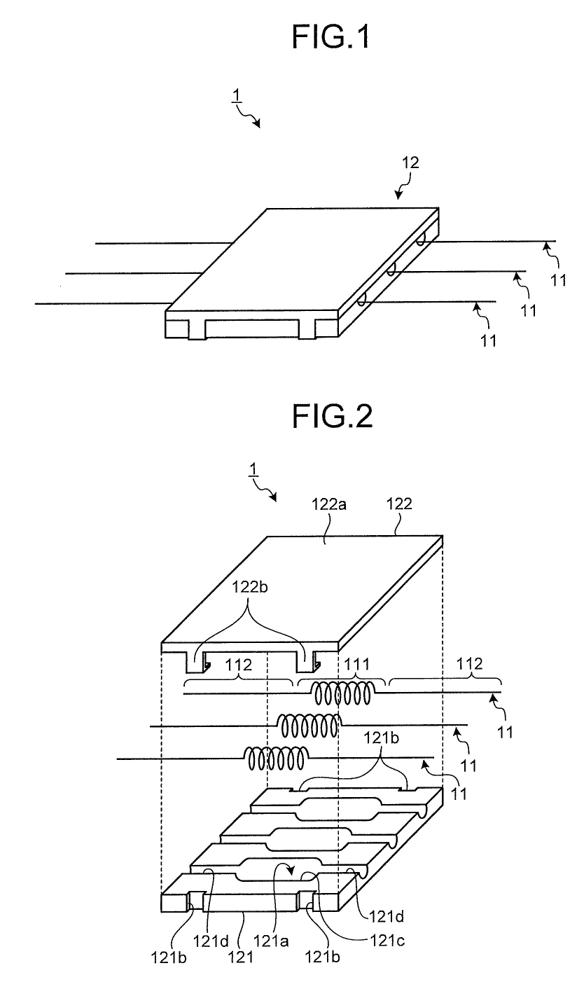

The configuration and the operation of a connection member 1 according to a first embodiment of the present invention will be explained below with reference to the drawings. FIG. 1 is a schematic diagram illustrating a schematic configuration of the connection member according to the first embodiment of the present invention. FIG. 2 is an exploded perspective view illustrating each component of the connection member according to the first embodiment of the present invention.

As shown in FIG. 1, the connection member 1 is connected to boards or the like at both ends to cause current to flow between the boards and includes elastic members 11 stretchable against the force applied from outside and a restraining member 12 that holds part of each elastic member 11.

As shown in FIG. 2, the elastic member 11 includes a coiled elastic portion 111 stretchable according to the force applied from outside the connection member 1 and linear contact portions 112 that are provided at both ends of the elastic portion 111 and cause current to flow between the boards by the ends thereof coming into contact with the boards. Examples of a conductive material used as the elastic member 11 include copper, beryllium copper, phosphor bronze, and silver-added copper.

The restraining member 12 has a rectangular parallelepiped shape formed by using an insulating material such as resin and includes a holding unit 121 that holds the elastic members 11 and a lid 122 that is locked to the holding unit 121 in a state of covering the upper portion of the holding unit 121. Moreover, the holding unit 121 includes a plurality of groove portions 121a, which are formed on one side of the rectangular parallelepiped, which extend in directions parallel to each other, and each of which holds the elastic member 11, and includes a plurality of recess portions 121b, which are formed on the sides on which groove portions 121a do not pass and which are perpendicular to the side on which the groove portions 121a are formed, and into which part of the lid 122 can be fit.

The groove portion 121a includes a first groove portion 121c and two second groove portions 121d extending from both ends of the first groove portion 121c. The first groove portion 121c can accommodate the elastic portion 111, has a length slightly larger than a natural length of the elastic portion 111 in a longitudinal direction, and has a length (width) slightly larger than the width of the elastic portion 111 in a lateral direction. Moreover, the second groove portion 121d can accommodate part of the contact portion 112 and has a central axis aligned with the central axis of the first groove portion 121c. In FIG. 1 and FIG. 2, the cross-sectional shape of each of the groove portions 121c and 121d is a semicircle, however, the shape may be a rectangle. Because the groove portions 121a each accommodate the elastic member 11, the elastic members 11 do not come into contact with each other. In the case shown in FIG. 2, the intervals between adjacent groove portions 121a are all the same, however, because the intervals are determined depending on the arrangement of electrodes on the boards, which are connection targets, all the intervals may not be the same.

The lid 122 includes a covering portion 122a covering the holding unit 121 and claw portions 122b that project in a direction perpendicular to the covering surface from the outer edge of the covering portion 122a and can fit into the recess portions 121b of the holding unit 121. The tip of the claw portion 122b is bent with respect to the direction in which the claw portion 122b extends and is locked to the surface, which is opposed to the surface on which the groove portions 121a are formed among the surfaces of the lid 122, when the lid 122 is attached to the holding unit 121.

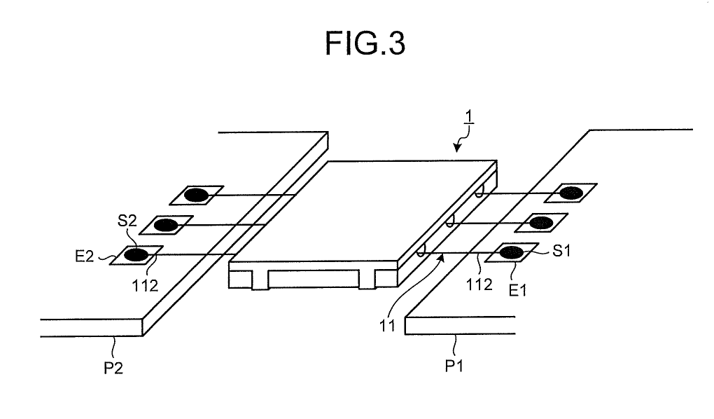

FIG. 3 is a diagram illustrating connection between the connection member 1 having the above configuration and boards P1 and P2. As shown in FIG. 3, the ends of the contact portions 112 are soldered to electrodes E1 and E2 of the boards P1 and P2 with solders S1 and S2. In such a manner, current can flow between the boards P1 and P2 by bringing the ends of the contact portions 112 into contact with the electrodes E1 and E2. In the case shown in FIG. 3, the contact portions 112 are connected to the electrodes E1 and E2, however, when the boards are provided with terminals, the contact portions 112 may be connected to the terminals.

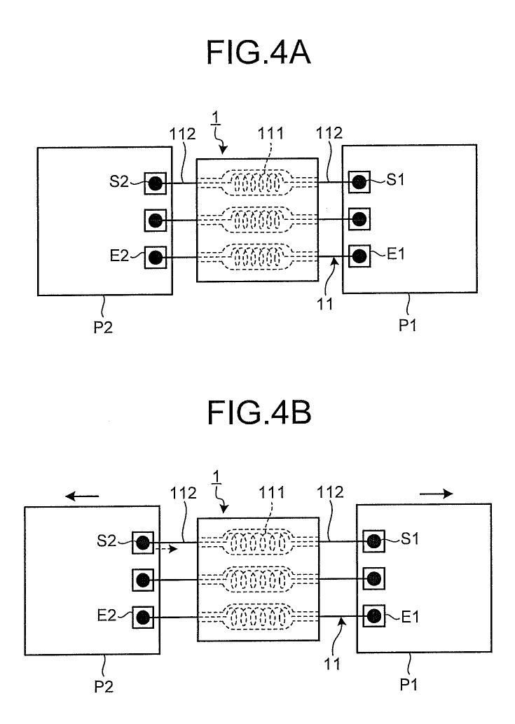

The operation of the elastic member 1 when the boards P1 and P2 vibrate will be explained with reference to FIGS. 4A and 4B. FIGS. 4A and 4B are diagrams illustrating an operation in response to vibrations of the connection member 1. First, in FIG. 4A, the connection member 1 is connected to the boards P1 and P2 arranged at a predetermined position. At this time, the coils of the elastic portions 111 have a natural length, i.e., no force is applied thereto from both sides.

Thereafter, as shown in FIG. 4B, when each of the boards P1 and P2 vibrates and the boards P1 and P2 move in a direction (see arrows in the figure) away from each other, the elastic portions 111 extend and therefore the elastic force in a direction (see dashed arrows in the figure) opposite to the moving direction is applied to the ends of the contact portions 112 in addition to the force in the moving direction. Therefore, the force applied to the contact portions 112 during vibrations becomes smaller than the case with no elastic portion 111, so that the solders S1 and S2 can be prevented from being stripped from the electrodes E1 and E2 or from being damaged. In order to correspond even to vibrations of small amplitude, the diameter of the elastic member 11 is preferably 0.2 mm or less.

In FIGS. 4A and 4B, even when the direction of the vibrations of the boards P1 and P2 is a vertical direction, the same effect can be obtained by the extension of the elastic portions 111.

According to the above-described first embodiment, when the boards vibrate, the elastic portions of the connection member extend and compress to relax the force applied to the solders in a direction opposite to the moving direction of the boards, so that stripping or damage of the solders, which fix connection between the connection member and the electrodes, can be prevented. Moreover, because each groove portion formed on the restraining member holds the elastic member, the elastic members do not come into contact with each other, so that current can flow reliably to a corresponding electrode on the board.

In the first embodiment, a plurality of groove portions is provided on one side of the holding unit, however, the groove portions may be provided on a plurality of sides of the holding unit in a distributed fashion. The elastic members may be coated with insulating resin such as enamel. The elastic members can be insulated more securely by coating them with insulating resin.

### Second Embodiment

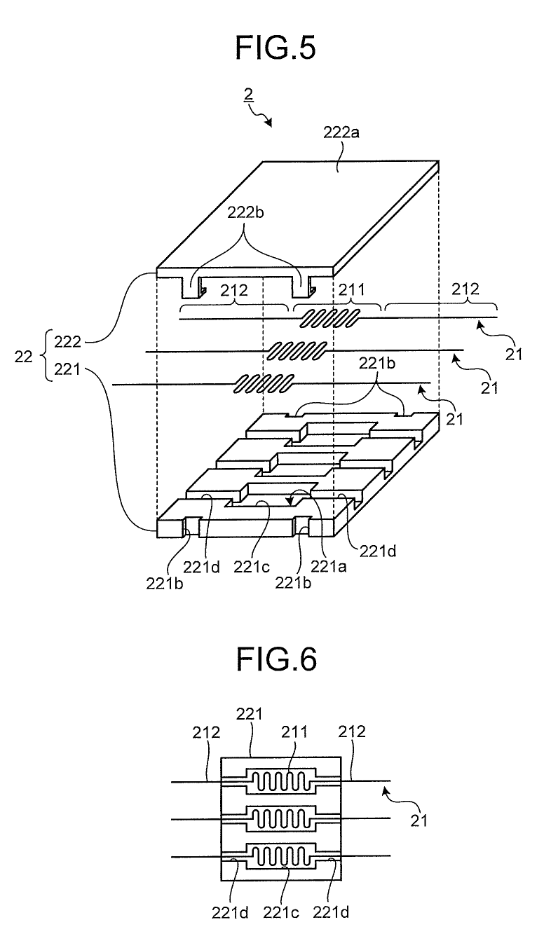

Next, the configuration of a connection member 2 according to a second embodiment of the present invention will be explained with reference to the drawings. FIG. 5 is an exploded perspective view illustrating each component of the connection member 2 according to the second embodiment of the present invention. FIG. 6 is a top view illustrating a configuration of a main part of the connection member 2 according to the second embodiment of the present invention.

As shown in FIG. 5, the connection member 2 according to the second embodiment includes elastic members 21 having a conductivity and an insulating restraining member 22 composed of a holding unit 221 that holds the elastic members 21 and a lid 222 that covers the surface of the holding unit 221. FIG. 6 illustrates a top view of the restraining member 22 shown in FIG. 5 with the lid 222 removed.

The elastic member 21 includes an elastic portion 211 having a zigzag shape in which shapes of the letter S are consecutive and two contact portions 212 that linearly extend along a plane (hereinafter, “zigzag surface”) including the entire portion in which the elastic portion 211 extends in a zigzag shape. The elastic portion 211 is formed into a flat shape having a thickness equal to the diameter of a wire rod.

The holding unit 221 includes a plurality of groove portions 221a, each of which accommodates and holds the elastic portion 211 and part of the contact portion 212 and which extend in directions parallel to each other, and includes a plurality of recess portions 221b, which are formed on the sides on which groove portions 221a do not pass and which are perpendicular to the side on which the groove portions 221a are formed, and into which part of the lid 222 can be fit. The groove portion 221a includes a first groove portion 221c and second groove portions 221d. Because the groove portions 221a each accommodate the elastic member 21, the elastic members 21 do not come into contact with each other. The bottom surface of the first groove portion 221c is formed to correspond to the zigzag surface of the elastic portion 211. The length of the first groove portion 221c in the longitudinal direction is larger than the natural length of the elastic portion 211. Moreover, the depth of the first groove portion 221c and the second groove portion 221d is slightly larger than the diameter of a wire rod.

The lid 222 includes a covering portion 222a covering the holding unit 221 and claw portions 222b that project in a direction perpendicular to the covering surface from the outer edge of the covering portion 222a and can fit into the recess portions 221b of the holding unit 221. The tip of the claw portion 222b is bent with respect to the direction in which the claw portion 222b extends and is locked to the surface, which is opposed to the surface on which the groove portions 221a are formed among the surfaces of the lid 222, when the lid 222 is attached to the holding unit 221.

The connection member according to the above-described second embodiment can be formed into a flat shape having a thickness of about a wire rod in a direction perpendicular to the zigzag surface, so that the restraining member can be formed thinner. Moreover, in the similar manner to the first embodiment, because the force applied to the solders can be relaxed by the elastic portions regardless of the vibration direction of the boards, a stable conduction state can be maintained even when the boards vibrate.

### Third Embodiment

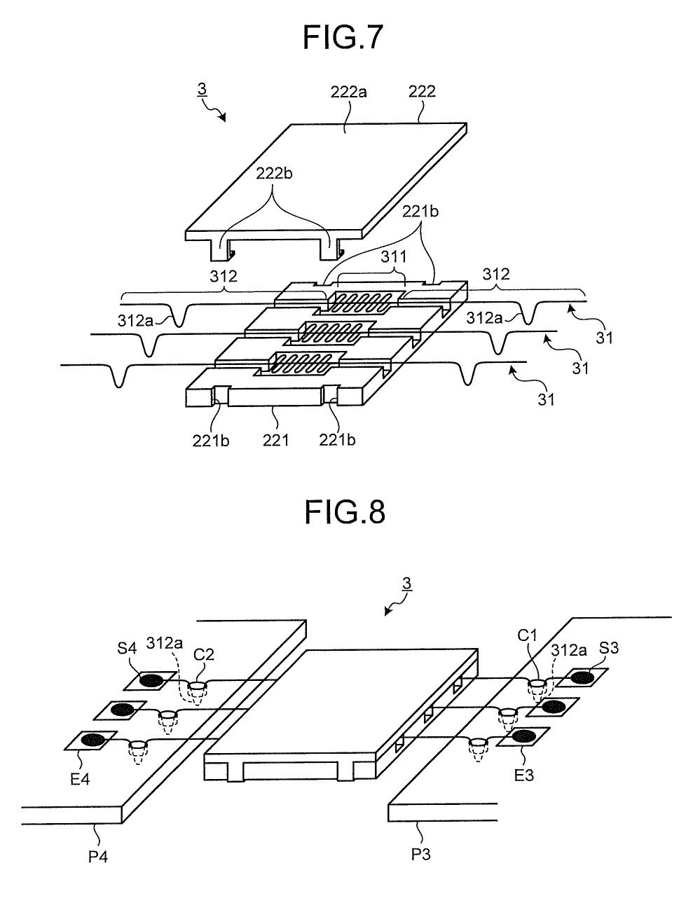

Next, the configuration of a connection member 3 according to a third embodiment of the present invention will be explained with reference to the drawings. FIG. 7 is an exploded perspective view illustrating each component of the connection member 3 according to the third embodiment of the present invention. Moreover, FIG. 8 is a diagram illustrating connection between the connection member 3 and boards P3 and P4 according to the third embodiment of the present invention.

The connection member 3 shown in FIG. 7 includes the above-described restraining member 22 (the holding unit 221 and the lid 222, see FIG. 5) and elastic members 31. The elastic member 31 has conductivity and includes an elastic portion 311 having a zigzag shape in which shapes of the letter S are consecutive and two contact portions 312 linearly extending along the S-shaped zigzag surface. The elastic portion 311 is formed into a flat shape having a thickness equal to the diameter of a wire rod. Moreover, the contact portion 312 includes a curved portion 312a convexly curved in a direction perpendicular to a direction in which the contact portion 312 extends.

As shown in FIG. 8, when the ends of the contact portions 312 of the connection member 3 are joined to electrodes E3 and E4 with solders S3 and S4, the curved portions 312a of the contact portions 312 are inserted into holes C1 and C2 provided in advance in boards P3 and P4, respectively. The curved portion 312a is deformable by the force applied to the contact portion 312. When being deformed, the force is applied to the contact portion 312 in a direction different from the direction in which the elastic portion 311 extends. Therefore, the force applied to the contact portion 312 in the moving direction of the board is further relaxed, so that stripping and damage of the solders due to vibrations can be prevented more securely. Moreover, the curved portions 312a are inserted into the holes C1 and C2 to function as positioning pins, so that the connection member 3 and the boards P3 and P4 can be connected more easily.

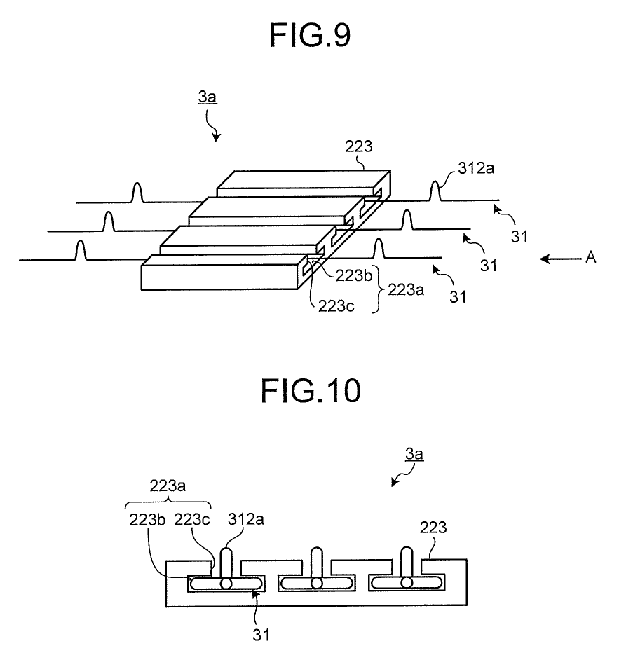

The connection member in the third embodiment can be configured only with the holding unit as a restraining member by changing the configuration of the groove portions. FIG. 9 is a top view illustrating a configuration of a connection member 3a that is a modified example of the third embodiment of the present invention, and FIG. 10 is a side view of the connection member 3a shown in FIG. 9 viewed from an arrow A direction.

The connection member 3a shown in FIGS. 9 and 10 includes the above-described elastic members 31 (see FIG. 7) and a holding unit 223 as a restraining member. The holding unit 223 has a rectangular parallelepiped shape capable of accommodating the elastic members 31 and includes a plurality of groove portions 223a which extend in directions parallel to each other and each of which holds the elastic member 31. The groove portion 223a includes an approximately columnar accommodation hole 223b extending through opposing side surfaces and an approximately columnar opening 223c that communicates with the accommodation hole 223b, has a width smaller than the accommodation hole 223b in a direction perpendicular to the penetrating direction of the accommodation hole 223b, and opens the upper surface of the holding unit 223.

When connecting the connection member 3a having the above configuration with the boards P3 and P4 shown in FIG. 8, the holding unit 223 is turned upside down so that the apexes of the curved portions face downward similarly to the connection member 3.

The connection member 3a is formed by inserting the elastic members 31 into the accommodation holes 223b from the side surface of the holding unit 223. At this time, the curved portion 312a formed vertically with respect to the holding unit 223 passes through the opening 223c, so that the connection member 3a can be formed by inserting the elastic members 31 into the holding unit 223 while not being retarded by the curved portions 312a.

Moreover, in the similar manner to the connection member 3 shown in FIGS. 7 and 8, the connection member 3a can relax vibrations from the boards and the curved portions 312a can function as positioning pins. If it is only intended to relax the force applied to the contact portion 312 in the moving direction of the board, the formation surface of the curved portion 312a may be formed parallel to the zigzag surface.

The connection member according to the above-described third embodiment can further relax the vibrations transmitted from the boards by providing the curved portions to the contact portions and facilitate connection between the contact members and the boards by the curved portions functioning as positioning pins. Especially, the third embodiment is effective when the elastic members have a relatively low stretchability, for example, when the diameter of the elastic members is 0.2 mm or more.

### Fourth Embodiment

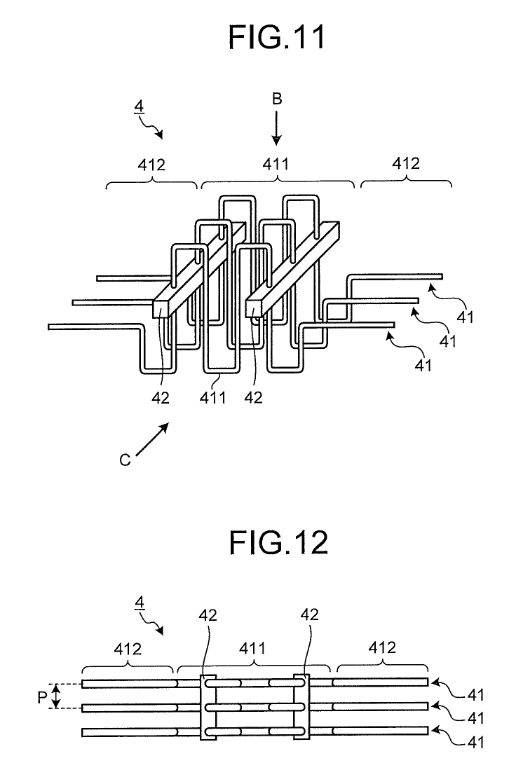

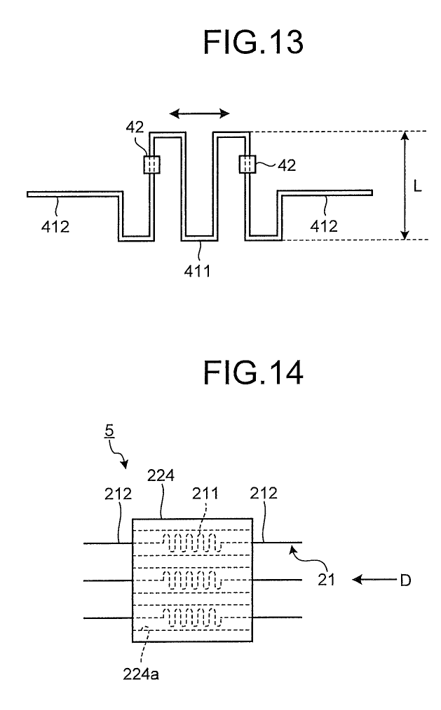

Next, the configuration of a connection member according to a fourth embodiment of the present invention will be explained with reference to the drawings. FIG. 11 is a perspective view illustrating the configuration of a connection member 4 according to the fourth embodiment of the present invention. Moreover, FIG. 12 is a top view of the connection member 4 shown in FIG. 11 viewed from an arrow B direction and FIG. 13 is a side view of the connection member 4 shown in FIG. 11 viewed from an arrow C direction.

The connection member 4 shown in FIG. 11 is connected to the boards or the like at both ends to cause current to flow between the boards and includes elastic members 41 stretchable against the force applied from outside and a plurality of restraining members 42 that hold part of each elastic member 41.

The elastic member 41 is formed of a wire rod and includes an elastic portion 411 stretchable (in an arrow direction in FIG. 13) according to the force applied from outside the connection member 4 and linear contact portions 412 that are provided at both ends of the elastic portion 411 and cause current to flow between the boards by the ends thereof coming into contact with the boards. Each elastic portion 411 has a zigzag shape in which shapes of the letter S are consecutive and is arranged such that the plane on which the contact portions 412 are arrayed and pass is perpendicular to the zigzag surface.

The restraining member 42 has a columnar shape and includes a plurality of approximately cylindrical holes extending through the opposite side surfaces of this column. The holes are provided to correspond to the elastic members 41 and cause part of each elastic member 41 to be inserted therethrough. Moreover, the holes have a cylindrical shape having a diameter approximately equal to that of the elastic member 41 and are arranged such that the central axes of the holes are parallel to each other. Consequently, the restraining members 42 hold the elastic members 41 in a state where the zigzag surfaces of the elastic members 41 are parallel to each other.

According to the connection member 4 having the above configuration, even when the elastic member 41 moves toward the adjacent elastic member 41, the elastic members 41 do not come into contact with each other, so that current can be made to flow stably. Moreover, in the connection member 4, because the width L (see FIG. 13) in a direction in which the zigzag shape reciprocates is larger than the interval P (see FIG. 12) of two adjacent elastic members 41, extension and compression of the elastic portion can be made large compared with the case where the zigzag surfaces of the elastic portions 211 of all the elastic members 21 are arrayed on the same plane such as the connection member 2 shown in FIG. 5. Therefore, even when the boards vibrate largely, it is possible to follow the movement of the boards. Moreover, even when the interval P is small, the force applied to the contact portions 412 due to vibrations can be relaxed.

The connection member according to the above-described fourth embodiment prevents the elastic members from coming into contact with each other by a plurality of the restraining members holding the elastic members to be parallel to each other and relaxes the vibrations from the boards by extension and compression of the elastic portions, and therefore can make current to flow stably and prevent stripping and damage of the solders. Moreover, each elastic member is arranged such that the zigzag surface of the elastic portion is perpendicular to the plane on which the contact portions is arrayed and the zigzag surfaces of the elastic portions are parallel to each other, enabling to be torsionally rigid and further relax the force in response to vibrations in any direction.

The arrangement of the restraining members 42 may be such that the contact portions 412 are inserted through the restraining members 42 and the restraining members 42 may be arranged at different heights from each other. The arrangement of the restraining members may be one other than the above so long as the elastic members 41 are held parallel to each other by the restraining members 42 and the elastic members 41 do not come into contact with each other, and, for example, the restraining members 42 may be arranged at a portion at which the elastic members are bent. Moreover, the contact portion 412 may have a curved portion having a shape similar to the curved portion 312a shown in FIG. 7.

### Fifth Embodiment

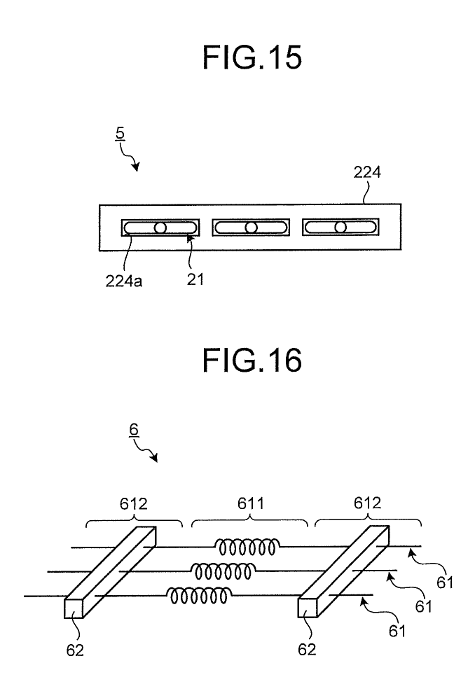

Next, the configuration of a connection member according to a fifth embodiment of the present invention will be explained with reference to FIGS. 14 and 15. FIG. 14 is a top view illustrating a configuration of a connection member 5 according to the fifth embodiment of the present invention and FIG. 15 is a side view of the connection member 5 shown in FIG. 14 viewed from an arrow D direction.

The connection member 5 shown in FIGS. 14 and 15 includes the above-described elastic members 21 (see FIG. 5) and a holding unit 224 as a restraining member that holds the elastic members 21. Accommodation holes 224a as approximately cylindrical holes, through which the elastic members 21 can be inserted, are formed in the holding unit 224. The connection member 5 can be formed by inserting the elastic members 21 through the accommodation holes 224a, so that an effect similar to the above-described connection member 2 can be obtained with a simpler configuration.

The connection member according to the above-described fifth embodiment can be formed into a flat shape having a thickness of about the diameter of a wire rod in a direction perpendicular to the zigzag surface, so that the restraining member can be formed thinner, and moreover, the elastic members can be held in the restraining member with a simple configuration and the force applied to the solders can be relaxed regardless of the vibration direction of the boards, so that a stable conduction state can be maintained.

After accommodating the elastic members 21 in the accommodation holes 224a, the accommodation holes 224a may be sealed with a cap or the like. The elastic members 21 can be prevented from dropping from the holding unit 224 by sealing the accommodation holes 224a.

Moreover, when the elastic portion has a coil shape of a circular cross section as shown in FIG. 2, it is sufficient to form the shape of the accommodation hole to correspond to the cross section. Furthermore, even in the case of the elastic member including a curved portion as shown in FIG. 7, if the distance between the elastic portion and the curved portion is sufficiently large (for example, the distance between the elastic portion and the curved portion is equal to or larger than the width of the restraining member), it is possible to insert the elastic portion through the accommodation hole by rotating the elastic member by 90° around the axis after inserting the curved portion through the accommodation hole.

### Sixth Embodiment

Next, a connection member according to a sixth embodiment will be explained with reference to FIG. 16. FIG. 16 is a perspective view illustrating the configuration of a connection member 6 according to the sixth embodiment of the present invention. In the connection member 6 shown in FIG. 16, each elastic member 61 composed of a coiled elastic portion 611 and contact portions 612 provided at both ends of the elastic portion 611 is held by restraining members 62 so that the linear contact portions 612 are inserted through the restraining members 62 and the contact portions are approximately parallel to each other.

The connection member according to the above-described sixth embodiment prevents the elastic members from coming into contact with each other by a plurality of the restraining members holding the elastic members to be parallel to each other and relaxes the vibrations from the boards by extension and compression of the elastic portions, and therefore can make current to flow stably and prevent stripping and damage of the solders. The elastic portions may be coated with insulating resin such as enamel.

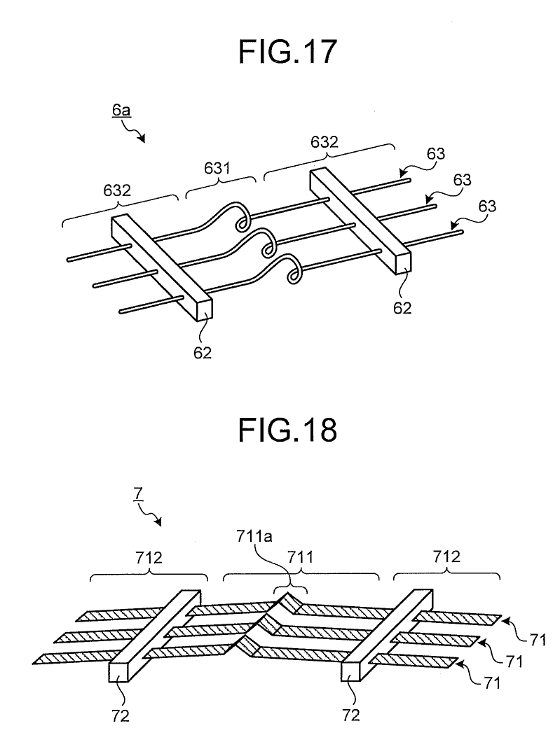

FIG. 17 is a perspective view illustrating a configuration of a connection member 6a that is a modified example of the sixth embodiment of the present invention. In the connection member 6a shown in FIG. 17, each elastic member 63 composed of an elastic portion 631 having a single-turn structure and contact portions 632 provided at both ends of the elastic portion 631 is held by the restraining members 62 at the contact portions 632.

The winding directions of the elastic portions 631 shown in FIG. 17 are aligned, however, the winding directions may not be aligned so long as the elastic members 63 are not in contact with each other.

### Other Embodiments

Next, the configuration of a connection member according to another embodiment of the present invention will be explained with reference to the drawings. FIG. 18 is a perspective view illustrating a configuration of a connection member 7 according to another embodiment of the present invention.

The connection member 7 shown in FIG. 18 is composed of elastic members 71, which are plate springs, and restraining members 72. The elastic member 71 includes a stretchable elastic portion 711 and contact portions 712 that come into contact with the boards to cause current to flow between the boards. The elastic member 71 has stretchability in a connection direction with the boards by being held by the restraining members 72 to tilt against the horizontal surface. Moreover, the elastic portion 711 improves stretchability by having a tilt portion 711a formed tilted with respect to other parts of the elastic portion.

The tilt of the tilt portion 711a changes due to the vibrations of the boards connected to the ends of the connection portions 712, so that the connection member 7 relaxes the force applied to the solders.

The connection member according to the above-described another embodiment is composed of the stretchable elastic members and the restraining members that prevent the elastic members from coming into contact with each other, and can attenuate the vibrations of the boards with a simple structure and thus relax the force applied to the solders.

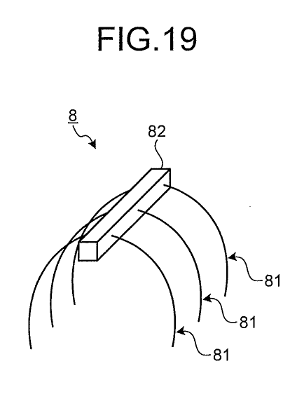

Moreover, FIG. 19 is a perspective view of a connection member 8 according to still another embodiment of the present invention. The connection member 8 shown in FIG. 19 is formed by a restraining member 82 holding elastic members 81 as single-turn springs. The connection member 8 can extend and compress in response to the vibrations of the boards by the bending of the single-turn springs, so that the connection member 8 can relax the force applied to the solders.

The end shape of the contact portion can be deformed according to the boards to be connected. Especially, the end of the contact portion 712 and the end of the elastic member 81 are preferably formed in parallel with or vertical to the boards for connection with the boards.

The connection members according to the first to sixth embodiments and other embodiments described above can adjust the length of the elastic member (the elastic portion and/or the contact portion) according to the distance between the members (between the boards) that are the connection targets. Moreover, the configuration of the restraining member can be changed according to the length of the elastic member.

The present invention is not limited to the configurations illustrated in the above-described embodiments and can be variously modified without departing from the gist thereof.

### (Note 1)

A connection member that connects different boards, comprising:

a plurality of conductive elastic members each of which includes two contact portions that are in contact with the different boards at ends, respectively, and an elastic portion that is provided between the two contact portions and is stretchable according to a force applied from outside the connection member; and

an insulating restraining member that restrains movement of each of the elastic members by holding part of each of the elastic members.

### (Note 2)

The connection member according to note 1, wherein a plurality of groove portions, which extend in directions parallel to each other and each of which holds at least the elastic portion, is formed on the restraining member.

### (Note 3)

The connection member according to note 2, wherein

the groove portion includes
an approximately columnar accommodation hole that accommodates and holds part of the elastic member, and
an approximately columnar opening that communicates with the accommodation hole and has a diameter smaller than a diameter of the accommodation hole.

### (Note 4)

The connection member according to note 2 or 3, wherein the groove portions are formed on one side of the restraining member.

### (Note 5)

The connection member according to any one of notes 2 to 4, wherein the restraining member further includes a lid that covers the groove portions.

### (Note 6)

The connection member according to note 1, wherein the restraining member has a rectangular parallelepiped shape, and includes a plurality of approximately cylindrical holes that have a cross-sectional shape, through which the elastic portion is capable of being inserted, and extend through opposite side surfaces of the rectangular parallelepiped shape.

### (Note 7)

The connection member according to any one of notes 1 to 6, wherein the elastic portion has a coil shape.

### (Note 8)

The connection member according to any one of notes 1 to 6, wherein the elastic portion has a zigzag shape repeating S shape.

### (Note 9)

The connection member according to note 1, wherein the elastic member is formed of a wire rod, and the restraining member includes a plurality of holes which have a diameter approximately equal to a diameter of the wire rod and through which part of the elastic member is inserted.

### (Note 10)

The connection member according to note 9, wherein the restraining member is such that planes that pass central axes of the holes are approximately parallel to each other.

### (Note 11)

The connection member according to note 9 or 10, wherein the elastic portion has a zigzag shape repeating S shape.

### (Note 12)

The connection member according to note 11, wherein

the elastic portions are such that formation surfaces of the zigzag shape are parallel to each other, and

a width in a direction in which the zigzag shape of the elastic portion reciprocates is larger than an interval between adjacent elastic members.

### (Note 13)

The connection member according to note 12, wherein

the contact portions are parallel to each other and pass a same plane, and

the plane is perpendicular to the formation surfaces of the zigzag shape.

### (Note 14)

The connection member according to note 9 or 10, wherein the elastic portion has a coil shape.

### (Note 15)

The connection member according to any one of notes 1 or 14, wherein the contact portion includes a convexly curved curved portion.

### INDUSTRIAL APPLICABILITY

As above, the connection member according to the present invention is useful, for example, when connecting members that vibrate and is especially suitable for connecting boards to cause current to flow between the boards.

### REFERENCE SIGNS LIST

1, 2, 3, 3a, 4, 5, 6, 6a, 7, 8 CONNECTION MEMBER

11, 21, 31, 41, 61, 63, 71, 81 ELASTIC MEMBER

12, 22, 42, 62, 72, 82 RESTRAINING MEMBER

111, 211, 311, 411, 611, 631, 711 ELASTIC PORTION

112, 212, 312, 412, 612, 632, 712 CONTACT PORTION

121, 221, 223, 224 HOLDING UNIT

121a, 221a, 223a GROOVE PORTION

121b, 221b RECESS PORTION

122, 222 LID

122a, 222a COVERING PORTION

122b, 222b CLAW PORTION

223b, 224a ACCOMMODATION HOLE

223c OPENING

312a CURVED PORTION

711a TILT PORTION

C1, C2 HOLE

E1 to E4 ELECTRODE

P1 to P4 BOARD

S1 to S4 SOLDER

1. A connection member that connects different boards, comprising:
a plurality of conductive elastic members each of which includes two contact portions that are in contact with the different boards at ends, respectively, and an elastic portion that is provided between the two contact portions and is stretchable according to a force applied from outside the connection member; and
an insulating restraining member that restrains movement of each of the elastic members by holding part of each of the elastic members.

2. The connection member according to claim 1, wherein a plurality of groove portions, which extend in directions parallel to each other and each of which holds at least the elastic portion, is formed on the restraining member.

3. The connection member according to claim 2, wherein
the groove portion includes
an approximately columnar accommodation hole that accommodates and holds part of the elastic member, and
an approximately columnar opening that communicates with the accommodation hole and has a diameter smaller than a diameter of the accommodation hole.

4. The connection member according to claim 2, wherein the groove portions are formed on one side of the restraining member.

5. The connection member according to claim 2, wherein the restraining member further includes a lid that covers the groove portions.

6. The connection member according to claim 1, wherein the restraining member has a rectangular parallelepiped shape, and includes a plurality of approximately cylindrical holes that have a cross-sectional shape, through which the elastic portion is capable of being inserted, and extend through opposite side surfaces of the rectangular parallelepiped shape.

7. The connection member according to claim 1, wherein
the elastic member is formed of a wire rod,
each of the elastic portions has a zigzag shape in which shapes of the letter S are consecutive,
formation surfaces of the zigzag shape are parallel to each other, and
a width in a direction in which the zigzag shape of the elastic portion reciprocates is larger than an interval between adjacent elastic members.

8. The connection member according to claim 7, wherein
the contact portions are parallel to each other and pass a same plane, and
the plane is perpendicular to the formation surfaces of the zigzag shape.
